(19) United States
(12) Patent Application Publication
(10) Pub. No.: US 2013/0153899 A1
(43) Pub. Date: Jun. 20, 2013

(54) SEMICONDUCTOR DEVICE HAVING PLURAL SEMICONDUCTOR CHIPS

(71) Applicant: Elpida Memory, Inc., Tokyo (JP)

(72) Inventors: Shoji WADA, Tokyo (JP); Toru ISHIKAWA, Tokyo (JP)

(73) Assignee: Elpida Memory, Inc., Tokyo (JP)

(21) Appl. No.: 13/720,875

(22) Filed: Dec. 19, 2012

(30) Foreign Application Priority Data
Dec. 20, 2011 (JP) 2011-278312

(51) Int. Cl. H01L 23/498

(52) U.S. Cl. CPC H01L 23/49816
USPC 257/48

(57) ABSTRACT

Disclosed herein is a device that including a first chip having first to fourth terminals and a second chip having fifth to seventh terminals. The first chip further includes a penetration electrode connected between the first and fourth electrodes and a first internal node coupled to of which an electrical potential being changed in response to an electrical potential of the first terminal. The second chip further includes a second internal node coupled to of which an electrical potential being changed in response to an electrical potential of the fifth terminal. The first internal node is electrically coupled to both the second terminal and the sixth terminal. The second internal node is electrically coupled to both the third terminal and the seventh terminal.

### BACKGROUND OF THE INVENTION

1. Field of the Invention

The present invention relates to a semiconductor device, and more particularly to a semiconductor device having a plurality of semiconductor chips.

2. Description of Related Art

In recent years, a semiconductor device of a stacked type has been well known. A semiconductor device of a stacked type includes a plurality of semiconductor chips that employ a plurality of penetration electrodes. The plurality of semiconductor chips are electrically connected via the penetration electrodes. According to this configuration, a plurality of the semiconductor chips can be packaged on the circuit substrate in high density.

Such a stacked semiconductor device needs to be tested whether input terminals of the semiconductor chips for signals to be supplied in common are electrically connected to outside properly.

In recent years, the number of input terminals of individual semiconductor chips in a stacked semiconductor device for signals to be input to in common has been increased. The increased number of input terminals increases time to perform a test operation. In order to reduce the test time, a boundary scan test method can be used. The boundary scan test method includes electrically connecting a plurality of input terminals of the semiconductor chips in a cascade, supplying an input signal to the input terminal of the first stage, and testing whether an expected output signal is output from the input terminal of the final stage.

For example, Japanese Patent Application Laid-Open No. H7-225258 discloses a technology for testing whether input terminals of a plurality of semiconductor chips are electrically connected to outside by using a boundary scan test method.

However, according to the boundary scan test method described in Japanese Patent Application Laid-Open No. H7-225258, there are input terminals that are not able to be tested whether electrically connected to outside. Examples of such input terminals include ones through which a control signal itself for controlling the boundary scan operation is supplied to the respective chips. Such terminals are input terminals of the semiconductor chips for signals to be supplied to in common. In other words, there has conventionally been a problem that input terminals that are connected to input terminals of other chips and therefore not capable of direct electrical contact and are not subjected to the boundary scan test method cannot be tested whether electrically connected to outside.

### SUMMARY

In one embodiment, there is provided a semiconductor device that includes: a first chip including first and second surfaces opposed to each other, first, second and third terminals on the first surface, and a fourth terminal on the second surface, the first and fourth terminals being electrically coupled to each other through a penetration electrode penetrating a semiconductor substrate of the first chip, and a first internal node of which an electrical potential being changed in response to an electrical potential of the first terminal; and a second chip stacked with the first chip, the second chip including a third surface facing to the second surface of the first chip, a fourth surface opposed to the third surface, a fifth terminal on the third surface electrically coupled to the fourth terminal of the first chip, sixth and seventh terminals on the third surface, and a second internal node of which an electrical potential being changed in response to an electrical potential of the fifth terminal; the first internal node of the first chip being electrically coupled to both the second terminal of the first chip and the sixth terminal of the second chip, the second internal node of the second chip being electrically coupled to both the third terminal of the first chip and the seventh terminal of the second chip.

### BRIEF DESCRIPTION OF THE DRAWINGS

FIG. 1 is a schematic chip diagram indicative of an embodiment of a semiconductor chip 10;

FIG. 2 is a schematic cross-sectional view of penetration electrodes TSV shown in FIG. 1;

FIGS. 3A and 3B are schematic cross-sectional views of a stacked semiconductor device 20 including a plurality of semiconductor chips 10 shown in FIG. 1;

FIGS. 4A to 4C are schematic diagrams of electrical connections between the semiconductor chips of the stacked semiconductor device 20;

FIG. 5 is a circuit block diagram of the semiconductor chip 10 shown in FIG. 1;

FIG. 6 is a diagram of a detailed configuration of an internal circuit unit 55a shown in FIG. 5;

FIG. 7 is a diagram of a detailed configuration of a BS circuit unit 53a shown in FIG. 5;

FIG. 8 is a circuit diagram showing a detailed configuration of the test circuit unit 51 shown in FIG. 5;

FIG. 9 is a waveform chart showing the operation of the test circuit unit 51 shown in FIG. 8;

FIG. 10 is a circuit diagram showing a detailed configuration of the test control circuit 52 shown in FIG. 5; and

FIG. 11 is a waveform chart showing the operation of the test circuit unit 52 shown in FIG. 10.

### DETAILED DESCRIPTION OF THE EMBODIMENTS

Hereinafter, a preferred embodiment of the present invention will be described in detail with reference to the accompanying drawings.

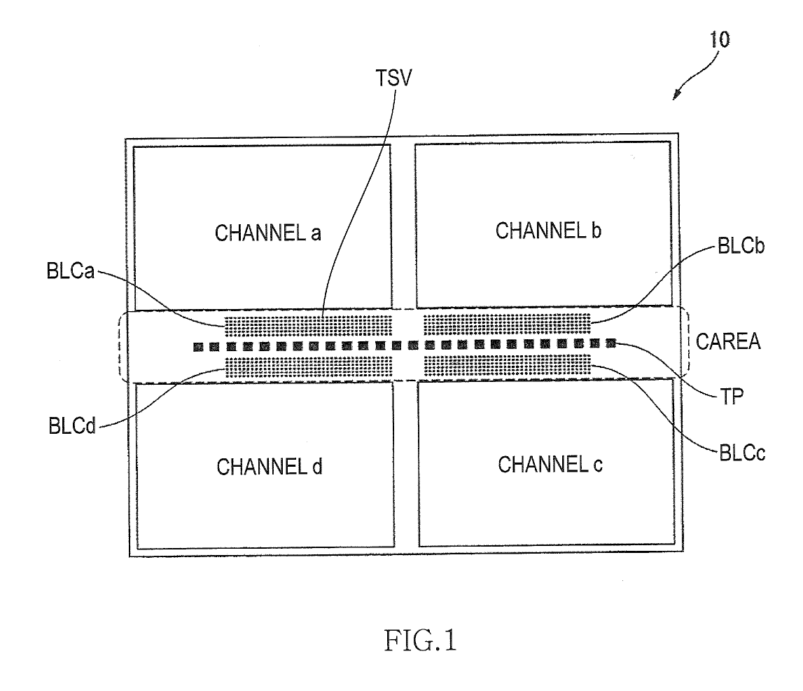

Referring now to FIG. 1, the semiconductor chip 10 includes four dynamic random access memories (DRAMs) having a volatile storing function which are arranged on a single semiconductor chip. The semiconductor chip 10 according to this embodiment is a memory chip, so-called wide I/O DRAM.

With such a configuration, channels a to d can transmit and receive data, commands, and addresses to/from outside the chip independently of each other. More specifically, the channels a to d can independently perform various types of operations such as a read operation, write operation, and refresh operation by using respective corresponding control circuits to be described later.

As shown in FIG. 1, a plurality of penetration electrodes TSV and test pads TP are arranged in the center area CAREA of the semiconductor chip 10. The plurality of penetration electrodes TSV (Through Silicon Via) are divided into penetration electrode TSV arrays BLCa to BLCd corresponding to the respective channels a to d. Each of the penetration electrode TSV arrays BLCa to BLCd formed in the respective corresponding blocks a to d includes: penetration electrodes as a plurality of signal terminals for transmitting and receiving data signals DQ, command address signals CA, and clock signals CK; penetration electrodes as a plurality of power supply terminals to which power supply voltages VDD, VSS, and the like are supplied; and a penetration electrode as a test terminal for transmitting and receiving a test signal.

The test pads TP are pads or terminals for connecting probes when testing the channels a to d in a wafer state. The test pads TP are formed to have a pad size and interval (pitch) greater than the electrode size and interval (pitch) of the penetration electrodes TSV so that probes can be easily connected. By using the test pads TP, the semiconductor chip can be tested in a wafer state without damaging the penetration electrodes TSV.

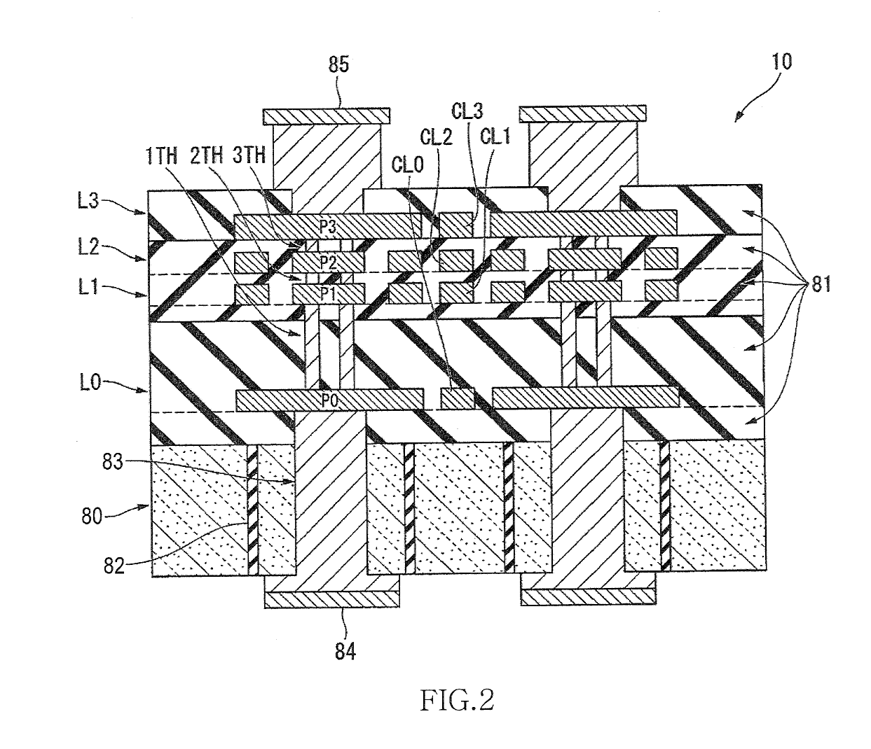

Turning to FIG. 2, two penetration electrodes TSV are shown.

The semiconductor chip 10 includes a semiconductor substrate 80, a plurality of interlayer insulation films 81 formed on the semiconductor substrate 80, and a multilayer wiring structure including layers L0 to L3. Although not shown in FIG. 2, various circuit elements for performing substantial functions of the semiconductor chip 10 are formed on the semiconductor substrate 80. The layers L0 to L3 constituting the multilayer wiring structure are covered with respective interlayer insulation films 81.

Each of the penetration electrodes TSV includes a substrate through portion 83, pad portions P0 to P3, through hole electrodes 1TH to 3TH, a surface bump electrode 85, and a backside bump electrode 84. The substrate through portion 83 penetrates through the semiconductor substrate 80 from the backside to the surface side, and further through the interlayer insulation film 81 that is formed between the semiconductor substrate 80 and the layer L0. The pad portions P0 to P3 are formed as the respective wiring layers of the multi layer wiring substrate. The through hole electrodes 1TH to 3TH vertically connect the pad portions.

The surface bump electrode 85 of each penetration electrode TSV is formed to protrude from the interlayer insulation films 81. The surface bump electrode 85 is connected to the topmost pad portion P3 through the interlayer insulation film 81 formed on the pad portion P3. The backside bump electrode 84 is formed to protrude from the backside of the semiconductor substrate 80 and connected to the substrate through portion 83. The surface bump electrode 85 and the backside bump electrode 84 function as terminals of the semiconductor chip 10.

The semiconductor substrate 80 includes insulation rings 82 which are formed to surround the substrate through portions 83. The insulation rings 82 electrically insulate the substrate through portions 83 from the areas of the semiconductor substrate 80 where various circuit elements are formed (transistor areas).

The multilayer wiring structure including the layers L0 to L3 is configured such that lower layers have higher resistance than upper layers. For example, in the present embodiment, the layer L0 is made of tungsten, W. The layers L1 to L3 are made of aluminum, Al. The topmost layer L3 has a thickness greater than those of the layers L1 and L2 for lower resistance.

Wiring layers CL0 to CL3 are formed as the layers L0 to L3, respectively. The wiring layers include various types of wiring such as signal wiring and power supply wiring. As shown in FIG. 2, the wiring layers CL0 to CL3 are also formed between adjoining penetration electrodes TSV.

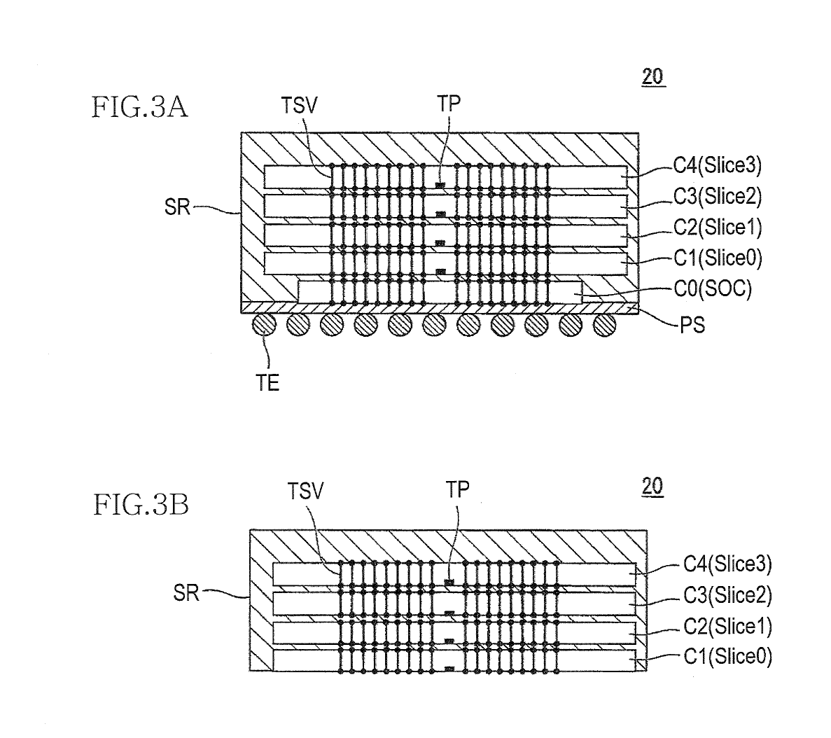

Turning to FIG. 3A, the stacked semiconductor device 20 includes five semiconductor chips mounted on a package substrate PS. Specifically, the stacked semiconductor device 20 includes semiconductor chips C0 to C4 stacked in this order from below. For example, the chip C0 is an SOC (System on Chip; controller chip) for controlling the stacked semiconductor device 20. The chips C1 (Slice0), C2 (Slice1), C3 (Slice2), and C4 (Slice3) each are a memory chip such as the semiconductor chip 10 shown in FIGS. 1 and 2. The semiconductor chips C0 to C4 are packaged by a seal resin SR.

In other words, the stacked semiconductor device 20 is a system in which the chips C0 to C4 are integrally packaged. As shown in FIG. 3B, the chips C1 to C4 excluding the chip C0 may constitute a semiconductor device as a semifinished product in which the chips C1 to C4 are integrally packaged. In such a semiconductor device, signals can be supplied to the test pads TP of the chip C1 to test whether each of the chips C1 to C4 operates in properly.

The chips C1 to C4, after stacked and molded in the stacked semiconductor device 20 as shown in FIG. 3A, each communicate only with the chip C0 under the control of the chip C0. The chip C0 communicates with outside through external terminals TE. The channels of the chips C1 to C4 may communicate with each other under the control of the semiconductor chip C0. Such communications are useful, for example, for data copy between channels and for data processing between channels pertaining to data processing in the chip C0 that is the SOC. The chips C1 to C4 each may be connected to outside through the chip C0 and the external terminals TE under the control of the chip C0. As will be described in detail later, the signals supplied from the chip C0 to the chips C1 to C4 may include signals that are passed through the chip C0 and supplied to the chips C1 to C4 without substantial logic operations of the chip C0. Such signals supplied to the chips C1 to C4 without substantial logic operations of the chip C0 can be used when testing the chips C1 to C4 after the chips C1 to C4 are stacked and molded to form the semiconductor device 20. The chips C1 to C4 that are memory devices are each divided into areas corresponding to the four channels a to d as shown in FIG. 1. Here, any number of chips may be stacked.

The corresponding terminals of the chips C0 to C4 are electrically connected to each other via penetration electrodes TSV which run through the stacked semiconductor device 20 in the stacking direction. A plurality of external terminals TE are formed on the bottom of the package substrate PS. The external terminals TE are electrically connected to corresponding groups of terminals of the chips C0 to C4.

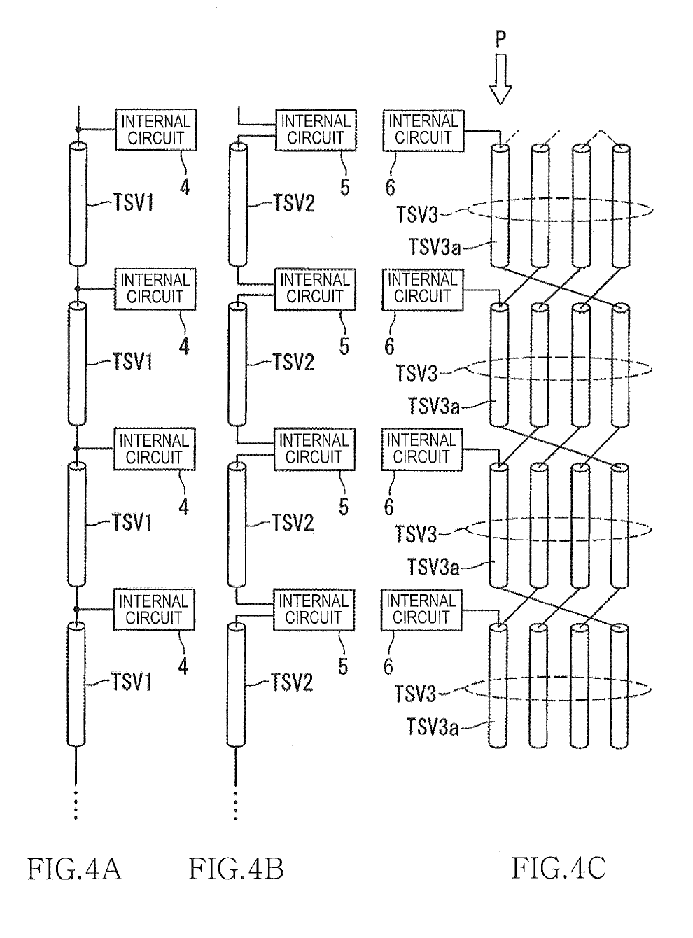

connections of the chips C1 to C4 shown in FIGS. 3A and 3B will be explained with reference to FIGS. 4A to 4C. That is, the penetration electrodes TSV shown on the bottom in FIGS. 4A to 4C are connected to the penetration electrodes TSV (not shown) of the chip C0 (SOC chip).

As shown in FIG. 4A, the penetration electrodes TSV1 that are vertically aligned or provided at the same position in plain view from the upper surface of the chip C4 are short-circuited, and one wiring line is configured by the penetration electrodes TSV1. The penetration electrodes TSV1 that are provided in the chips C1 to C4 are connected to internal circuits 4 provided in the respective chips. Accordingly, input signals (write data, command, and address) that are supplied from the chip C0 (SOC chip) to the penetration electrodes TSV1 shown in FIG. 4A are commonly input to the chips C1 to C4. Output signals (read data etc.) that are supplied from the chips C1 to C4 to the penetration electrodes TSV1 are wired-ORed and input to the chip C0.

Meanwhile, as shown in FIG. 4B, some penetration electrodes TSV2 are not directly connected to penetration electrodes of the other chips provided at the same position in planar view but are connected to the penetration electrodes TSV2 of the other chips through the internal circuit 5 provided in the corresponding chip. That is, the internal circuits 5 that are provided in the chips C1 to C4 are cascade-connected through the penetration electrodes TSV2. This kind of penetration electrodes TSV2 are used to sequentially transmit predetermined information to the internal circuits 5 provided in the chips C1 to C4.

As to another part of the penetration electrodes TSV, a penetration electrode TSV3 is short-circuited to penetration electrodes TSV3 of the other chips provided at the different position in planar view, as shown in FIG. 4C. With respect to this kind of penetration electrodes TSV3, internal circuits 6 of the chips C1 to C4 are connected to penetration electrodes TSV3a provided at the predetermined position P in planar view. Thereby, information can be selectively input to the internal circuit 6 provided in each chip. This kind of penetration electrode TSV3 is used for transfer test clock enable signals tCKEk (k=1 to 4 which corresponds to that there are the chips C1 to C4) and test chip selection signals tCSk (k=1 to 4) in a boundary scan operation described later.

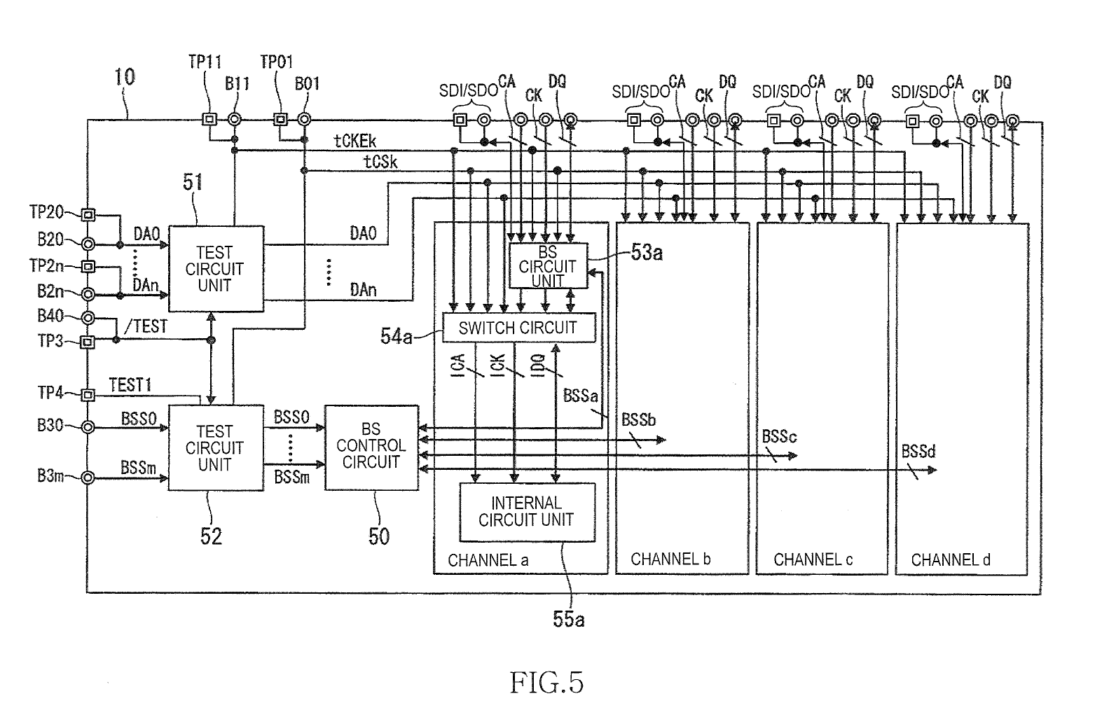

A circuit block diagram of the chip C1 will be explained with reference to FIG. 5. Since the chips C1 to C4 have substantially the same circuit configuration, the circuit configuration of the chip C1 will be described with reference to FIG. 5.

As shown in FIG. 5, the chip C1 includes the channels a to d, a boundary scan control circuit 50 (hereinafter, BS control circuit 50), a test circuit unit 51, and a test circuit unit 52. The chip C1 further includes a plurality of bump electrodes “BXX” (represented by double circles in FIG. 5) and a plurality of test pads “TPY” or “TPYY” (represented by double squares in FIG. 5). That is, the reference symbols “BXX” denote respective bump electrodes, and the reference symbols “TPY” or “TPYY” respective test pads. The bump electrodes BXX correspond to the surface bump electrodes 85 and backside bump electrodes 84 of the penetration electrodes TSV shown in FIG. 2.

When the test operation, test signals are not directly supplied to the bump electrodes BXX via probes of a tester. This is because the bump electrodes BXX are small in size and are arranged in very fine pitch so that it is difficult to contact the probes of the tester to the bump electrodes BXX. In addition, it is necessary to avoid damages of the bump electrodes BXX caused by contacting the probes.

When the test operation, the test signals are supplied to the test pads “TPY” or “TPYY” via probes of the tester. Because the chip C1 is the lowermost semiconductor chip as shown in FIG. 3B, the test pads “TPY” or “TPYY” of the chip C1 are exposed without covered with the seal resin SR whereas the test pads “TPY” or “TPYY” of the other chips C2 to C4 are covered with the seal resin SR. In the test operation, hence, the test signals are supplied to the test pads “TPY” or “TPYY” of the chip C1 via probes of the tester.

As shown in FIG. 5, the semiconductor chip 10 also includes a plurality of bump electrodes for command address signals CA, clock signals CK, and data signals DQ. These bump electrodes are used during a normal operation. The bump electrodes for the normal operation are provided separately from the bump electrodes for the test operation.

The external terminals TE shown in FIG. 3A are electrically connected to the bump electrodes for the normal operation. The bump electrodes for the test operation are not electrically connected to the external terminals TE.

The test circuit unit 51 buffers direct access signals DA0 to DAn supplied from bump electrodes B20 to B2n or test pads TP20 to TP2n, and outputs the direct access signals DA0 to DAn to the switch circuit 54a. A test operation using a test signal /TEST will be described later in conjunction with the configuration of the test circuit unit 51. In a test operation that includes boundary scan, the switch circuit 54a transmits and receives such signals without the intermediary of the BS circuit unit 53a.

As employed herein, the direct access signals DA refer to signals that the chips C1 to C4 stacked on the chip C0, or SOC chip, shown in FIG. 3A transmit and receive to/from outside the stacked semiconductor device 20 without substantial arithmetic processing of the SOC chip. The direct access signals DA include a test command address, a test clock, and test data.

The penetration electrodes TSV corresponding to the bump electrodes B11 and B01 to which the test clock enable signal tCKEk (k=1) and the test chip selection signal tCSk (k=1) are supplied, respectively, are composed of spirally-connected penetration electrodes TSV3 shown in FIG. 4C. In the present embodiment, four penetration electrodes TSV3 laterally juxtaposed in FIG. 4C may be referred to respectively as penetration electrodes from the left so as to correspond to the test clock enable signals tCKEk (k=1 to 4). Four penetration electrodes TSV3 laterally juxtaposed in FIG. 4C may be penetration electrodes TSV3Sa, TSV3Sb, TSV3Sc, and TSV3Sd, respectively, so as to correspond to the test chip selection signal tCSk (k=1 to 4). Such penetration electrodes are arranged in the same positions on the planes of the chips C1 to C4, and electrically connected to external terminals TE of the stacked semiconductor device 20 without the intermediary of the chip C0.

Consequently, if, in a test operation, the test clock enable signals tCKEk (k=1 to 4) are supplied to the bump electrodes B11 to B14 (or test pads TP11 to TP14) of the chip C1, respectively, the test signals can be individually, i.e., selectively supplied to the bump electrodes B11 and test pads TP11 of the chips C1 to C4, respectively.

If the test chip selection signals tCSk (k=1 to 4) are supplied to the bump electrodes B01 to B04 of the chip C1, respectively, the test signals can be individually, i.e., selectively supplied to the bump electrodes B01 and test pads TP01 of the chips C1 to C4, respectively.

In other words, while FIG. 5 shows the chip C1, the test clock enable signals tCKEk (k=1 to 4) are selectively supplied to the bump electrodes B11 and test pads TP11 of the chips C1 to C4, respectively. The test chip selection signals tCSk (k=1 to 4) are selectively supplied to the bump electrodes B01 and test pads TP01 of the chips C1 to C4, respectively.

The test clock enable signals and the test chip selection signals used in a test operation shall be included in the test clock and the test command address, respectively. Clock enable signals and chip selection signals used in a normal operation shall be included in the clock signal and the command address signal, respectively.

The switch circuit 54a selects either the command address signals CA or the test command address, either the clock signals CK or the test clock signals, and either the data signals DQ or the test data signals, and supplies the selected ones to the internal circuit unit 55a as internal command address signals ICA, internal clock signals ICK, and internal data signals IDQ, respectively.

A circuit configuration and its function of the semiconductor chip 10 will be explained below.

The semiconductor chip 10 has four channels a to d each functions as an individual DRAM. The configuration of each channel will initially be described by using the channel a as an example. Since the channels b to d have substantially the same circuit configuration as the channel a, description thereof will be omitted.

The channel a includes a boundary scan circuit unit 53a (BS circuit unit 53a), a switch circuit 54a, and an internal circuit unit 55a.

The BS circuit unit 53a is connected with a plurality of bump electrodes. Signals to be transmitted and received in a normal operation, namely, command address signals CA, clock signals CK, and data signals DQ are input/output to/from the BS circuit unit 53a.

Specifically, the chip C0 transmits and receives the command address signals CA, clock signals CK, and data signals DQ through paths formed by penetration electrodes TSV1 shown in FIG. 4A (fourth paths).

The BS circuit unit 53a transmits and receives such signals to/from the switch circuit 54a. The BS circuit unit 53a includes input/output buffers for such signals (to be described in detail later).

The switch circuit 54a is connected to the BS circuit unit 53a, as well as to a common node between a bump electrode B11 and a test pad TP11, a common node between a bump electrode B01 and a test pad TP01, and the test circuit unit 51.

The test enable signal tCKEk (k=1) is supplied from the bump electrode B11 or the test pad TP11. The test chip selection signal tCSk (k=1) is supplied from the bump electrode B01 or the test pad TP01. A plurality of direct access signals DA0 to DAn are supplied from the test circuit unit 51.

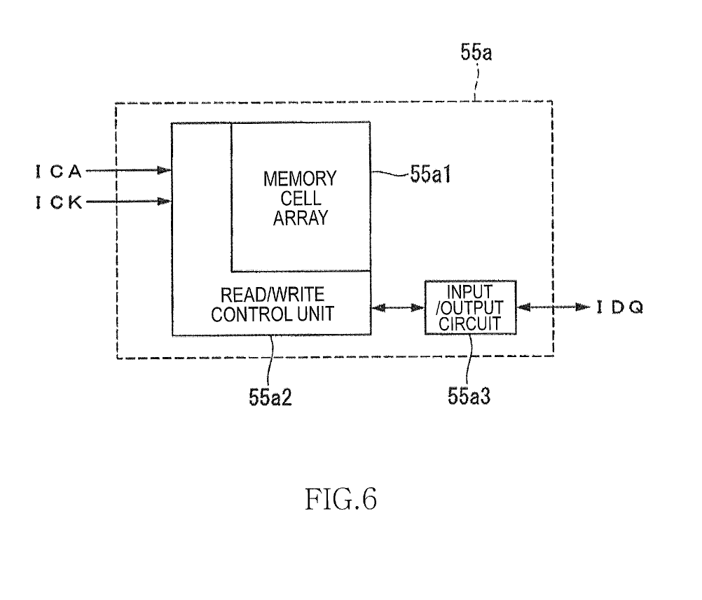

Each channel includes an internal circuit unit 55a. A circuit configuration of the internal circuit unit 55a is shown in FIG. 6.

As shown in FIG. 6, the internal circuit unit 55a includes a memory cell array 55a1, a read and write control unit 55a2, and an input/output circuit 55a3. The memory cell array 55a1 includes a plurality of memory cells.

The read and write control unit 55a2 is a circuit that controls various types of operations inside the internal circuit unit 55a, such as a read operation, write operation, and refresh operation, according to the internal clock signals ICK and the internal command address signals ICA supplied from the switch circuit 54a. The read and write control unit 55a2 accesses the memory cells in the memory cell array 55a1 according to the internal command address signals ICA, and in a read operation, outputs read data stored in the memory cells to the input/output circuit 55a3. In a write operation, the read and write control unit 55a2 stores write data output from the input/output circuit 55a3 into the memory cells in the memory cell array 55a1.

The input/output circuit 55a3, in a read operation, outputs read data received from the memory cell array 55a1 to the switch circuit 54a as the internal data signals IDQ. In a write operation, the input/output circuit 55a3 outputs the internal data signals IDQ supplied from the switch circuit 54a to the memory cell array 55a1 as write data.

The internal command address signals ICA, the internal clock signals ICK and the internal data signals IDQ are generated in each of the channels a to d based on the command address signals CA, the clock signals CK and the data signals DQ supplied to each of the channels a to d. The command address signals CA, the clock signals CK and the data signals DQ are supplied via respective bump electrodes provided in each channel.

The semiconductor chip 10 shown in FIG. 5 can perform two types of test operations.

One of the test operations is performed with respect to the internal circuit unit 55 included in each channel by using a test circuit unit 51. This test includes various test operations such as an evaluating test of retaining time of memory cells, a timing test of control signals, and the like.

The other of the test operations is a boundary scan test (BS test) by using a test circuit unit 52. The BS test is performed in order to detect a disconnection between bump electrodes for the command address signals CA, the clock signals CK and the data signals DQ. The BS test will be explained in detail later.

A switch circuit 54a select either one of the test operations.

One of important features of the present embodiment is to detect a disconnection or open defect of signal paths including penetration electrodes TSV and bump electrodes provided in the chips C1 to C4. This is because these two types of test operation cannot be performed properly if a disconnection occurs in the signal paths.

Therefore, in one of the test operations, a disconnection of the signal paths that are constituted of the penetration electrodes TSV and the bump electrodes B2k (k=0 to n) that corresponds to DAk is detected. In the other of the test operations, a disconnection of the signal paths that are constituted of the penetration electrodes TSV and the bump electrodes B31 (1=0 to m) that corresponds to BSS1 is detected.

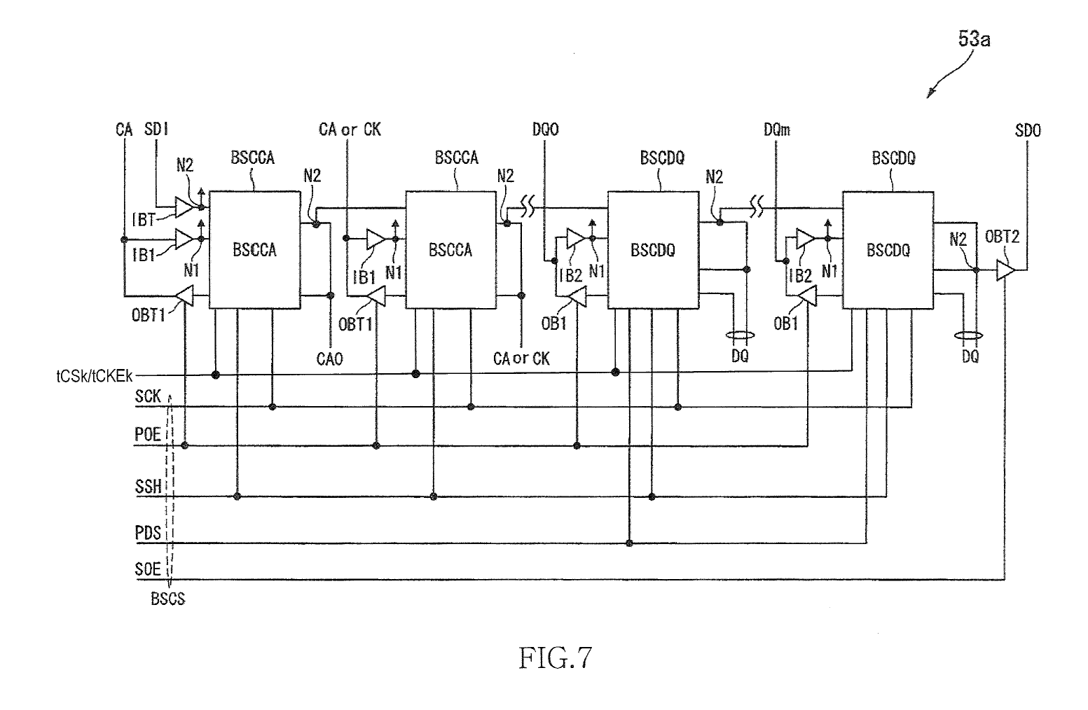

The detailed configuration of the BS circuit unit 53a will be explained with reference to FIG. 7. A function of each signals shown in FIG. 7 will be explained at first.

A scan clock signal SCK is a synchronous clock signal for the boundary scan circuits BSCCA and BSCDQ to perform a latch operation and an output operation.

A parallel out enable signal POE is used to enable the boundary scan circuits BSCCA and BSCDQ to output the signals stored therein in parallel to the respective bump electrodes when activated. For example, although the command address signals CA are input signals and are not output from the chips C1 to C4, the command address signals CA can be output from the chips C1 to C4 by activating a buffer circuit OBT1 in the test operation.

A serial parallel input selection signal SSH is used to enable the boundary scan circuits BSCCA and BSCDQ to latch a test signal supplied from a node N2 in the test operation. During a normal operation, the boundary scan circuits BSCCA and BSCDQ latch a signal supplied from a node N1.

A parallel output data selection signal PDS is used to enable the boundary scan circuits BSCCA and BSCDQ to output a test signal stored therein to a buffer circuit OB1 in the test operation. During a normal operation, the boundary scan circuits BSCCA and BSCDQ output a data signal DQ to the buffer circuit OB1.

A serial output enable signal SOE is used to enable the boundary scan circuits BSCCA and BSCDQ to output a test signal stored therein in serial to a buffer circuit OBT2 in the test operation. During a normal operation, the buffer circuit OBT2 is kept in an inactive state.

The detailed configuration of the BS circuit unit 53a will be explained with reference to FIG. 7.

The BS circuit unit 53a can receive the command address signals CA, the clock signals CK, and the data signals DQ in series as a plurality of scan data input signals SDI instead of receiving the signals from the respective corresponding bump electrodes in parallel. The BS circuit unit 53a can also receive the command address signals CA, the clock signals CK, and the data signals DQ from the respective corresponding bump electrodes in parallel, retain the signals inside, and output the retained signals from a scan data output buffer (output buffer OBT2) in series.

In FIG. 7, input buffers IB1 are input buffers intended for the command address signals CA or clock signals CK. Input buffers IB2 are input buffers intended for the data signals DQ. The input nodes of the input buffers are connected to the bump electrodes shown in FIG. 5 to which the respective input signals are supplied. An input buffer IBT is an input buffer intended for the scan data input signal SDI.

The input buffers each buffer an input signal supplied thereto, and outputs the buffered signal to a boundary scan circuit BSCCA or BSCDQ connected thereto.

In FIG. 7, output buffers OB1 are output buffers intended for data signals DQ. Output buffers OBT1 are output buffers for outputting the command address signals CA or clock signals CK.

The input nodes of the output buffers OB1 are connected to the boundary scan circuits BSCDQ. The output nodes of the output buffers OB1 are connected to the input nodes of the input buffers IB2 and the bump electrodes shown in FIG. 5 through which the data signals DQ are input/output.

The input nodes of the output buffers OBT1 are connected to the boundary scan circuits BSCCA. The output nodes of the output buffers OBT1 are connected to the input nodes of the input buffers IB1 and the bump electrodes shown in FIG. 5 to which the command address signals CA or clock signals CK are supplied.

The output buffers OBT1 are used only in a test operation that includes boundary scan. The output buffers OBT1 are not used in a normal operation since the command address signals CA and the clock signals CK are input only.

The boundary scan circuits BSCCA and BSCDQ fetch the signals supplied to the nodes N1 or N2 and retain the signals inside according to the logic of the serial/parallel input selection signal SSH, respectively. The nodes N1 and N2 are the two input nodes of each of the boundary scan circuits BSCCA and BSCDQ. The node on the output side of the input buffer IB1 or IB2 is referred to as N1. Another node is referred to as N2. In other words, the output node of each boundary scan circuit constitutes the input node N2 of the boundary scan circuit in the next stage. Such nodes N2 are connected to the switch circuit 54a. The node between the output node of the boundary scan circuit BSCDQ in the final stage and the input node of the output buffer OBT2 also serves as a node N2. The boundary scan circuits BSCDQ each further include an input node that is not connected to the node N2, i.e., not connected to the boundary scan circuit in the next stage or the output buffer OBT2. Such input nodes are connected with the switch circuit 54a, and the data signals DQ from the switch circuit 54a are input thereto. Meanwhile, the boundary scan circuits BSCCA only output signals to the switch circuit 54a and do not input any signal from the switch circuit 54a. Unlike the boundary scan circuits BSCDQ, the boundary scan circuits BSCCA do not have two signal lines connected to the switch circuit 54a. Only the nodes N2 are connected to the switch circuit 54a.

In a normal operation, for example, when the serial/parallel input selection signal SSH is at an “L” level, the boundary scan circuits BSCCA and BSCDQ fetch the command address signals CA, clock signals CK, and data signals DQ supplied from the corresponding bump electrodes through the input buffers IB1 or IB2 and the nodes N1, respectively. The boundary scan circuits BSCCA and BSCDQ retain the fetched signals inside thereof, and output the signals to the switch circuit 54a through the nodes N2, respectively.

In a test operation in which boundary scan is performed, for example, when the serial/parallel input selection signal SSH is at an “H” level, the boundary scan circuits BSCCA and BSCDQ fetch the signals supplied through the nodes N2 in synchronism with the scan clock signal SCK, respectively. The boundary scan circuits BSCCA and BSCDQ retain the fetched signals inside thereof, and output the signals to the input nodes N2 of the next stages, respectively.

In a normal operation, for example, when the parallel output data selection signal PDS is at an “L” level, the boundary scan circuits BSCDQ output the data signals DQ supplied from the switch circuit 54a to the output buffers OB1, respectively.

In a test operation in which boundary scan is performed, for example, when the parallel output data selection signal PDS is at an “H” level, the boundary scan circuits BSCDQ output the signals which themselves retain to the output buffers OB1, respectively.

In a test operation in which boundary scan is performed, for example, when the parallel out enable signal POE is at an “H” level, the boundary scan circuits BSCCA output the signals which themselves retain through the output buffers OBT1 to the corresponding bump electrodes, respectively.

In a test operation in which boundary scan is performed, for example, when the parallel out enable signal POE is at an “H” level, the boundary scan circuits BSCDQ output the signals which themselves retain through the output buffers OB1 to the corresponding bump electrodes, respectively.

As described above, when the parallel out enable signal POE is activated, the BS circuit unit 53a (boundary scan circuits BSCCA and BSCDQ) performs a parallel output operation.

When the serial output enable signal SOE is activated, the BS circuit unit 53a performs a serial output operation to output the signals retained in the respective boundary scan circuits from the output buffer OBT2 in succession as the scan data output signal SDO.

The BS test is performed by using these signals described above. For example, the BS test to detect an open defect between the chips C1 and C2 is performed by a following sequence.

At first, the test signal tCKE1 and tCS1 are activated in order to select the chip C1. Then, a plurality of test data are supplied in serial from a test pad SDI. The test signals are latched in the boundary scan circuits BSCCA and BSCDQ in response to the serial parallel input selection signal SSH. That is, the boundary scan circuits BSCCA and BSCDQ constitute a shift register circuit connected via the nodes N2.

Next, the parallel out enable signal POE is activated. Thus, the test data stored in the boundary scan circuits BSCCA and BSCDQ are output in parallel to the chips C2 to C4 via respective penetration electrodes TSV and the bump electrodes.

Next, the test signal tCKE2 and tCS2 are activated in order to select the chip C2 instead of the chip C1. Then, the serial parallel input selection signal SSH is deactivated. A plurality of test data supplied from the chip C1 in parallel are stored in the boundary scan circuits BSCCA and BSCDQ of the chips C2 accordingly.

Finally, the serial parallel input selection signal SSH and the serial output enable signal SOE are activated. A plurality of test data stored in the boundary scan circuits BSCCA and BSCDQ of the chips C2 are output in serial to the scan data output terminal SDO accordingly.

Because the scan data output terminal SDO of the chip C2 is electrically connected to the test pad SDO of the chip C1, the test data output to the scan data output terminal SDO can be obtained via the test pad SDO of the chip C1. For example, in the case where the test data having “HHHH” in logic level are supplied in serial to the scan data input terminal SDI, if the test data output from the scan data output terminal SDO are “HHLH” in logic level in this order, an open defect in the third signal path including the penetration electrode TSV and the bump electrode can be detected.

The test operation described the above is just one example of the BS test. The other types of test operations can be performed by using the circuit shown in FIG. 7.

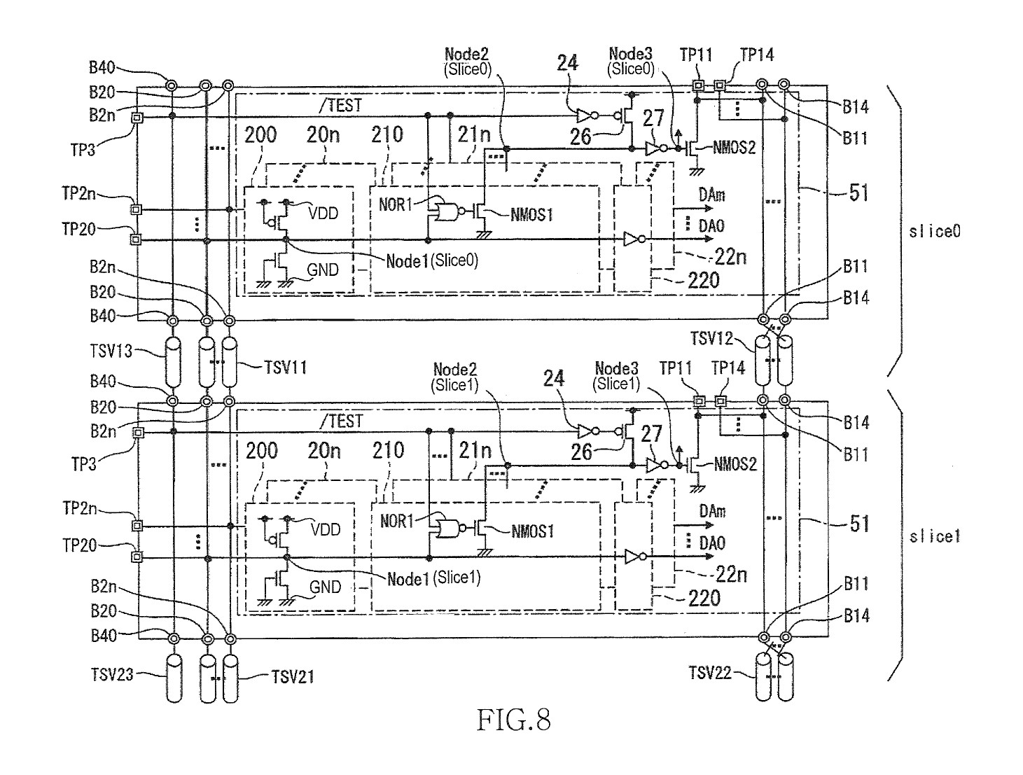

A circuit configuration of the test circuit unit 51 is explained in detail with reference to FIG. 8. The test circuit unit 51 is used to perform one of the operation tests described with reference to FIG. 5.

The test pads and bump electrodes shown in FIG. 8 are designated by the same reference symbols as those of the test pads and bump electrodes shown in FIG. 5.

A plurality of penetration electrodes TSV11, a plurality of penetration electrodes TSV12, and a penetration electrode TSV13 are formed in the same chip C1 as Slice0, for example. A plurality of penetration electrodes TSV21, a plurality of penetration electrodes TSV22, and a penetration electrode TSV23 are formed in the same chip C2 as Slice1, for example.

The plurality of penetration electrodes TSV11, the plurality of penetration electrodes TSV21, the penetration electrode TSV13, the penetration electrode TSV23, and the like each have a configuration of the penetration electrode TSV1 shown in FIG. 4A. The bump electrodes B40 of the chips C1 to C4 are connected to the penetration electrodes TSV13, TSV23, etc. The bump electron B20 to B2n are connected to the respective corresponding penetration electrodes TSV11, TSV21, etc. In other words, the bump electrodes B40 and B20 to B2n of the respective chips are connected in common via such penetration electrodes. When signals are supplied from outside the stacked semiconductor device 20 to the test pads TP3 and TP20 to TP2n of the chip C1, the signals are supplied to the bump electrodes of the chips C1 to C4 in common.

For example, suppose that the test signal /TEST is supplied from the test pad TP3 or the bump electrode B40 of the chip C1. Then, the test signal /TEST supplied to the test pad TP3 of the chip C1 (Slice0) can be supplied to the bump electrodes B40 of the chips C2 to C4 (Slice1 to Slice3) via the penetration electrodes TSV23 etc. Instead of providing the dedicated test pads, test pads or bump electrodes intended for, e.g., a reset signal may be used.

The signals (second signals) supplied to the test pads TP20 to TP2n of the chip C1 can be supplied to the bump electrodes B20 to B2n and the test pads TP20 to TP2n of the chips C2 to C4 (Slice1 to Slice3) via the penetration electrodes TSV21 etc.

Now, the penetration electrodes TSV12 are spirally-connected penetration electrodes TSV3 shown in FIG. 4C. Each chip includes four penetration electrodes.

The test pad TP11 of the chip C1 is connected to the bump electrode B11 of the chip C1. The bump electrode B11 of the chip C1 is connected to the bump electrode B12 of the chip C2 via the penetration electrode (a penetration electrode TSV12 shown in FIG. 8). The bump electrode B12 of the chip C2 is connected to the bump electrode B13 of the chip C3 via the penetration electrode (a penetration electrode TSV22 shown in FIG. 8). The bump electrode B13 of the chip C3 is connected to the bump electrode B14 of the chip C4 via a penetration electrode (not shown in FIG. 8).

Consequently, when a signal is supplied to the test pad TP11 of the chip C1, the signal can be supplied to the bump electrode B11 and the test pad TP11 of the chip C1 alone without being supplied to the bump electrodes B11 and the test pads TP11 of the chips C2 to C4.

Similarly, the test pad TP12 of the chip C1 is connected to the bump electrode B12 of the chip C1. The bump electrode B12 of the chip C1 is connected to the bump electrode B13 of the chip C2 via the penetration electrode (a penetration electrode TSV12 shown in FIG. 8). The bump electrode B13 of the chip C2 is connected to the bump electrode B14 of the chip C3 via the penetration electrode (a penetration electrode TSV22 shown in FIG. 8). The bump electrode B14 of the chip C3 is connected to the bump electrode B11 of the chip C4 via a penetration electrode (not shown in FIG. 8).

Consequently, when a signal is supplied to the test pad TP12 of the chip C1, the signal can be supplied to the bump electrode B11 and the test pad TP11 of the chip C4 alone without being supplied to the bump electrodes B11 and the test pads TP11 of the chips C1 to C3.

Similarly, the test pad TP13 of the chip C1 is connected to the chip electrode B13 of the chip C1. The bump electrode B13 of the chip C1 is connected to the bump electrode B14 of the chip C2 via the penetration electrode (a penetration electrode TSV12 shown in FIG. 8). The bump electrode B14 of the chip C2 is connected to the bump electrode B11 of the chip C3 via the penetration electrode (a penetration electrode TSV22 shown in FIG. 8). The bump electrode B11 of the chip C3 is connected to the bump electrode B12 of the chip C4 via a penetration electrode (not shown in FIG. 8).

Consequently, when a signal is supplied to the test pad TP13 of the chip C1, the signal can be supplied to the bump electrode B11 and the test pad TP11 of the chip C3 alone without being supplied to the bump electrodes B11 and the test pads TP11 of the chips C1, C2, and C4.

Similarly, the test pad TP14 of the chip C1 is connected to the bump electrode B14 of the chip C1. The bump electrode B14 of the chip C1 is connected to the bump electrode B11 of the chip C2 via the penetration electrode (a penetration electrode TSV12 shown in FIG. 8). The bump electrode B11 of the chip C2 is connected to the bump electrode B12 of the chip C3 via the penetration electrode (a penetration electrode TSV22 shown in FIG. 8). The bump electrode B12 of the chip C3 is connected to the bump electrode B13 of the chip C4 via a through penetration (not shown in FIG. 8).

Consequently, when a signal is supplied to the test pad TP14 of the chip C1, the signal can be supplied to the bump electrode B11 and the test pad TP11 of the chip C2 alone without being supplied to the bump electrodes B11 and the test pads TP11 of the chips C1, C3, and C4.

As described above, when signals are supplied to the test pads TP11 to TP14 of the chip C1 (Slice0) and the gate potentials of the NMOS transistors NMOS2 are changed, a potential change occurs on the bump electrodes B11 and the test pads TP11 of the chips C1 to C4 (Slice0 to Slice3). This makes it possible to obtain the test result (whether a current flows through third paths including the penetration electrodes TSV12) on each chip (slice).

Next, the circuit connection between the internal circuits of the test circuit unit 51 in the chip C1 will initially be described. Note that the chips C1 to C4 have the same circuit configuration.

The test pad TP20 and the bump electrode B20 are connected to an electrostatic breakdown protection element 200, a test circuit 210, and an input buffer 220.

The electrostatic breakdown protection element 200 includes, for example, a series circuit of a parasitic PMOS transistor and a parasitic NMOS transistor. The test pad TP20 is connected to the common node (referred to as a node Node1 (Slice 0)) of the series circuit. When a positive high voltage is applied to the test pad TP20 in a normal operation, the electrostatic breakdown protection element 200 releases the charge from the node Node1 (Slice 0) to the ground (GND) through the NMOS transistor. The electrostatic breakdown protection element 200 thereby protects the circuits connected to the node node1 from electrostatic breakdown. When a negative high voltage is applied to the test pad TP20 in a normal operation, the electrostatic breakdown protection element 200 releases the charge from the node Node1 (Slice 0) to the power supply (VDD) through the PMOS transistor. The electrostatic breakdown protection element 200 thereby protects the circuits connected to the node Node1 from electrostatic breakdown.

The test circuit 210 includes a NOR circuit NOR1 and an NMOS transistor NMOS1. Either one of two input nodes of the NOR circuit NOR1 is connected to the test pad TP3 and the bump electrode B40. The other of the two input nodes is connected to the node Node1 (Slice 0). The output node of the NOR circuit NOR1 is connected to the gate electrode of the NMOS transistor NMOS1.

The drain of the NMOS transistor NMOS1 is connected to a node Node2 (Slice 0). The gate electrode thereof is connected to the output node of the NOR gate NOR1. The source is grounded.

The input node of the input buffer 220 is connected to the node Node1 (Slice 0). The output node of the input buffer 220 is connected to the switch circuit 54a shown in FIG. 5. The input buffer 220 buffers the direct access signal DA0 supplied to the bump electrode B20 or the test pad TP20, and outputs the direct access signal DA0 to the switch circuit 54a.

Like the test pad TP20 and the bump electrode B20, the test pads TP21 to TP2n and the bump electrodes B21 to B2n are connected to the same respective circuits as the electrostatic breakdown protection element 200, the test circuit 210, and the input buffer 220.

Hereinafter, the electrostatic breakdown protection element, the test circuit, and the input circuit connected to a test pad TP2i and a bump electrode B2i (i=0 to n) will be referred to as an electrostatic breakdown protection element 20i, a test circuit 21i, and an input buffer 22i, respectively. The input buffers 22i buffer the direct access signals DAi supplied to the bump electrodes B2i or test pads TP2i, and output the direct access signals DAi to the switch circuit 54a.

In each test circuit 21i (i=0 to n), either one of the two input nodes of the NOR circuit NOR1 is connected to the test pad TP3 and the bump electrode B40. The drains of the NMOS transistors NMOS1 of the test circuits 21i are connected to the node Node2 (Slice 0).

The input node of an inverter circuit 24 is connected to the test pad TP3 and the bump electrode B40, to which the test signal /TEST is supplied. The output node of the inverter circuit 24 is connected to the gate electrode of a PMOS transistor 26. The source of the PMOS transistor 26 is connected to the power supply VDD, and the drain is connected to the node Node2 (Slice 0).

The node Node2 (Slice 0) is connected to the input node of an inverter circuit 27. The output node of the inverter circuit 27 is connected to a node Node3 (Slice 0). The gate electrode of the NMOS transistor NMOS2 is connected to the node Node3 (Slice 0). The drain of the NMOS transistor NMOS2 is connected to the test pad TP11 and the bump electrode B11. The source thereof is grounded.

Next, an operation for detecting a defective connection of the input terminals of the chips C1 to C4, i.e., the terminals that are not capable of direct contact from outside nor subjected to the boundary scan test method by using the foregoing configuration will be described.

The following description is given on the assumption that the connection between the bump electrode B2n formed on the chip C1 (Slice0) and the bump electrode B2n formed on the chip C2 (Slice1) via a penetration electrode TSV11 is open, i.e., electrically disconnected.

In the test operation using the test circuit unit 51, the test signals are directly supplied to the pads TP2k (k=0 to n) and the pad TP3.

When supplying H level to the pads TP2k (k=0 to n) and 1 level to the test pad TP3 of the lowermost chip C1, an output signal of the gate circuit NOR1 becomes L level because the node Node1 is in H level. The transistor NMOS1 is brought into OFF state accordingly. In the test circuit unit 51, a plurality of the transistors NMOS1 are provided corresponding to the pads TP2k (k=0 to n). Drains of the transistors NMOS1 are electrically connected in common to the node Node2. If all the transistors NMOS1 are OFF state, the test pads TP11 to TP14 are brought into a high impedance state because the transistor NMOS2 turns OFF. When predetermined potentials are supplied to the test pads TP11 to TP14, these potentials are not changed accordingly.

However, if an open defect exists in at least one of the signal paths including the penetration electrodes TSV11 and TSV13, the bump electrodes B2k (k=0 to n) and the bump electrode B40 provided between the chips C1 and C2, at least one of the nodes Node1 in the chip C2 is not changed to H level and kept in L level. Accordingly, at least one of the transistors NMOS1 in the chip C2 turns ON because at least one of the gate circuits NOR1 in the chip C2 outputs H level. The node Node2 is discharged to the ground level and therefore the transistor NMOS2 turns ON. Accordingly, a corresponding test pad TP1x is changed from the high impedance state to the ground potential. Thus, the open defect between the chips C1 and C2 can be detected by monitoring the potential of the test pads TP11 to TP14.

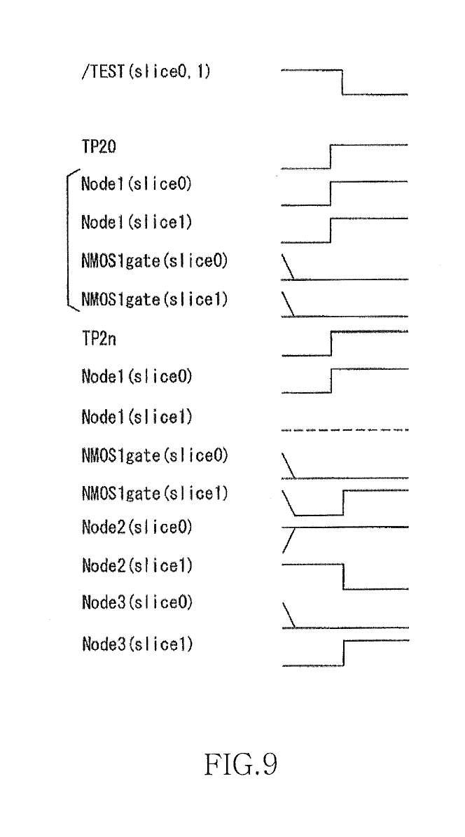

The penetration electrodes TSV12 and TSV22 are spirally-connected as shown in FIG. 4C. Therefore, a defect point can be specified by monitoring the potential of the test pads TP11 to TP14. When the open defect does not exist, the test pads TP11 to TP14 are kept in the floating state as shown in FIG. 9.

FIG. 9 shows potential changes on key nodes of the chips C1 and C2. The names of the nodes are accompanied by parenthesized slice names to provide a distinction between the chips C1 and C2. For example, the node Node1 of the chip C1 is referred to as Node1 (Slice0). The node Node1 of the chip C2 is referred to as Node1 (Slice1).

In the following description, the test pads TP20 to TP2n are typified by the test pad TP20 except the test pad TP2n.

In the chip C1 (Slice0), the test signal /TEST of an “H” level is input to the test pad TP3. Signals of an “L” level are input to the test pads TP20 and TP2n.

When the signal of an “L” level is supplied to the test pad TP20 of the chip C1, the node Node1 (Slice0) connected to the test pad TP20 of the chip C1 becomes an “L” level.

When the signal of an “L” level is supplied to the test pad TP2n of the chip C1, the node Node1 (Slice0) connected to the test pad TP2n of the chip C1 becomes an “L” level.

Since the penetration electrode TSV11 between the bump electrode B20 of the chip C1 and the bump electrode B20 of the chip C2 properly connects the chips C1 and C2, the node Node1 (Slice1) connected to the test pad TP20 of the chip C2 also becomes an “L” level.

On the other hand, the penetration electrode TSV11 between the bump electrode B2n of the chip C1 and the bump electrode B2n of the chip C2 is open and does not connect the chips C1 and C2. The node Node1 (Slice1) connected to the test pad TP2n of the chip C2 therefore becomes a floating “L” level. The floating “L” level refers to that the potential of the node Node1 is at an “L” level because there is no current path to precharge the node Node1 to an “H” level.

The output node of the inverter circuit 24 connected to the test pad TP3 of the chip C1 becomes an “L” level. The PMOS transistor 26 whose gate electrode is connected to the inverter circuit 24 turns on, and the node Node2 (Slice0) is precharged to an “H” level. The penetration electrode TSV13 between the bump electrode B40 of the chip C1 and the bump electrode B40 of the chip C2 properly connects the chips C1 and C2. The output node of the inverter circuit 24 connected to the test pad TP3 of the chip C2 therefore becomes an “L” level. The PMOS transistor 26 whose gate electrode is connected to the inverter circuit 24 turns on, and the node Node2 (Slice1) is precharged to an “H” level.

Next, signals of an “H” level are supplied to the test pads TP20 and TP2n of the chip C1 (Slice0).

When the signal of an “H” level is supplied to the test pad TP20 of the chip C1, the node Node1 (Slice0) connected to the test pad TP20 of the chip C1 becomes an “H” level.

When the signal of an “H” level is supplied to the test pad TP2n of the chip C1, the node Node1 (Slice0) connected to the test pad TP2n of the chip C1 becomes an “H” level.

Since the penetration electrode TSV11 between the bump electrode B20 of the chip C1 and the bump electrode B20 of the chip C2 properly connects the chips C1 and C2, the node Node1 (Slice1) connected to the test pad TP20 of the chip C2 also becomes an “H” level.

On the other hand, the penetration electrode TSV11 between the bump electrode B2n of the chip C1 and the bump electrode B2n of the chip C2 is open and does not connect the chips C1 and C2. The node Node1 (Slice1) connected to the test pad TP2n of the chip C2 therefore maintains the floating “L” level.

Next, the test signal /TEST input to the test pad TP3 of the chip C1 is changed from the “H” level to an “L” level.

The output node of the inverter circuit 24 connected to the test pad TP3 of the chip C1 becomes an “L” level. The PMOS transistor 26 connected to the inverter circuit 24 turns off, and the node Node2 (Slice0) becomes a floating “H” level.

The penetration electrode TSV13 between the bump electrode B40 of the chip C1 and the bump electrode B40 of the chip C2 properly connects the chis C1 and C2. The output node of the inverter circuit 24 connected to the test pad TP3 of the chip C2 therefore becomes an “H” level. The PMOS transistor 26 connected to the inverter circuit 24 turns off, and the node Node2 (Slice1) becomes a floating “H” level. The floating “H” level refers to that the potential of the node Node2 (first layer) is at an “H” level because there is no current path for the potential of the node Node2 (first layer) once precharged to an “H” level to be discharged to an “L” level.

When the test signal /TEST supplied to the test pad TP3 of the chop C1 is changed from the “H” level to the “L” level, the NMOS transistors NMOS1 in the test circuits 210 and 21n of each chip (slice) make the following on/off operations.

The NOR circuit NOR1 in the test circuit 210 of the chip C1 maintains its output at an “L” level because the other input connected to the node Node1 (Slice0) is at an “H” level. Consequently, the NMOS transistor NMOS1 in the test circuit 210 of the chip C1 will not turn on.

The NOR circuit NOR1 in the test circuit 21n of the chip C1 maintains its output node at an “L” level because the other input node connected to the node Node1 (Slice0) is at an “H” level. Consequently, the NMOS transistor NMOS1 in the test circuit 21n of the chip C1 will not turn on.

The NOR circuit NOR1 in the test circuit 210 of the chip C2 maintains its output node at an “L” level because the other input node connected to the node Node1 (Slice1) is at an “H” level. Consequently, the NMOS transistor NMOS1 in the test circuit 210 of the chip C2 will not turn on.

In contrast, the NOR circuit NOR1 in the test circuit 21n of the chip C2 changes its output node to an “H” level because the other input node connected to the node Node1 (Slice1) is at a floating “L” level. The NMOS transistor NMOS1 in the test circuit 21n of the chip C2 therefore turns on.

In the chip C1, the NMOS transistors NMOS1 in the test circuits 210 to 21n are all off. The node Node2 (Slice0) of the chip C1 is thus maintained at a floating “H” level. The inverter circuit 27 connected to the node Node2 (Slice0) therefore maintains the node Node3 (Slice0) at an “L” level.

The potential of the gate electrode of the NMOS transistor NMOS2 in the chip C1 therefore remains at an “L” level. Even if a signal of an “H” level is applied to the test pad TP11 of the chip C1, no current flows through the NMOS transistor NMOS2 of the chip C1. The applied signal of the “H” level therefore undergoes no potential change.

Note that the test pads TP11 of the chips C2 to C4 are not connected to the test pad TP11 of the chip C1 since the penetration electrodes including the bump electrodes connected to the test pads are spirally connected as described above. The test pads TP11 of the chips C2 to C4 have no effect on the potential change of the signal of an “H” level applied to the test pad TP11 of the chip C1.

In the chip C2, the NMOS transistor NMOS1 in the test circuit 21n is on. This changes the node Node2 (Slice1) of the chip C2 from the floating “H” level to an “L” level. The inverter circuit 27 connected to the node Node2 (Slice1) therefore changes the node Node3 (Slice1) from an “L” level to an “H” level.

Consequently, the potential of the gate electrode of the NMOS transistor NMOS2 in the chip C2 changes from an “L” level to an “H” level. When a signal of an “H” level is applied to the test pad TP14 of the chip C1, a current flows through the NMOS transistor NMOS2 of the chip C2 and a potential change occurs on the signal of the “H” level applied to the test pad TP14 of the chip C1.

The test pads TP11 of the chips C1, C3, and C4 are not connected to the test pad TP11 of the chip C2 since the penetration electrodes including the bump electrodes connected to the test pads are spirally connected as described above. The test pads TP11 of the chips C1, C3, and C4 thus have no effect on the potential change of the signal of the “H” level applied to the test pad TP14 of the chip C1.

As has been described above, the stacked semiconductor device 20 includes a first semiconductor chip (chip C1) and a second semiconductor chip (chip C2).

The chip C2 (second semiconductor chip) includes a test circuit arranged between its own terminals (bump electrodes B20 to B2n) and input buffers (input buffers 220 to 22n). The test circuit (test circuit unit 51) includes anode (node Node2 (Slice1) of the chip C2) that is charged according to a first signal (test signal /TEST) supplied from the chip C1 (first semiconductor chip) and is discharged according to second signals (signals that are input to the test pads TP20 to TP2n of the first chip C1 and input to the nodes Node1 (Slice1) of the second chip C2 through the bump electrodes B20 to B2n, respectively) supplied from the chip C1 (first semiconductor chip).

The stacked semiconductor device 20 also includes a first path that transfers the first signal (test signal /TEST) from the chip C1 (first semiconductor chip) to the second chip (chip C2). The first path includes a penetration electrode (penetration electrode TSV13 which connects the bump electrode B40 of the chip C1 and the bump electrode B40 of the chip C2). The stacked semiconductor device 20 further includes paths (second paths) that transfer the second signals (signals that are input to the test pads TP20 to TP2n of the first chip C1 and input to the nodes Node1 (Slice1) of the second chip C2 through the bump electrodes B20 to B2n, respectively) from the chip C1 (first semiconductor chip) to the second chip (chip C2). The paths include penetration electrodes TSV11 (penetration electrodes) that connect the bump electrodes B20 to B2n of the chip C1 to the bump electrodes B20 to B2n of the chip C2, respectively.

The second signals are supplied to the input buffers (input buffers 220 to 22n) of the second semiconductor chip. If the second paths include any defect such as an open penetration electrode, the corresponding node Node1 (Slice1) fails to be provided with a second signal, whereby the potential of the node (node Node2 (Slice1)) is discharged.

To detect the potential change on the node (node Node2 (Slice1)), the chip C1 (first chip) and the chip C2 (second chip) include third paths including penetration electrodes (paths including the penetration electrodes TSV12). The third paths are capable of independently inputting signals from outside the semiconductor device to the respective chips and pass a current according to the potential of the node (node Node2 (Slice1)).

Consequently, if any one of the penetration electrodes TSV11 and the like that connect the chips (slices) has a defective connection, a current flows through the path (third path) that is connected to the one of the test pads TP11 to TP14 of the chip C1 corresponding to that slice. This makes it possible to determine the slice where the second paths including the penetration electrodes TSV11 and the like have the defective connection.

If the penetration electrode TSV13 connecting the bump electrode B40 of the chip C1 and the bump electrode B40 of the chip C2 is defective, the test pad TP3 of the chip C2 becomes a floating “L” level and the node (node Node2 (Slice1)) becomes an “L” level. This turns on the NMOS transistor NMOS2 of the chip C2. When a signal is input to the test pad TP14 of the chip C1, the signal undergoes a potential change, from which it can be determined that a defect lies in the paths from the chip C1 to the input buffers of the chip C2 including TSV13.

The third paths are configured to be selectively connected to a single chip. Conventional open check can thus be performed, for example, by providing an electrostatic breakdown protection element 200 on the common node between the bump electrode B11 and the test pad TP11 of each chip. For example, a negative potential may be applied to the common node to test whether a current flows through the NMOS transistor of the electrostatic breakdown protection device 200, thereby detecting the presence or absence of a defect in the third path. Alternatively, without the provision of the electrostatic breakdown protection element 200, a defect of a third path may be detected by applying a high voltage to the bump electrode B11 or the test pad TP11 of each chip and determining whether a current flows through the NMOS transistor NMOS2.

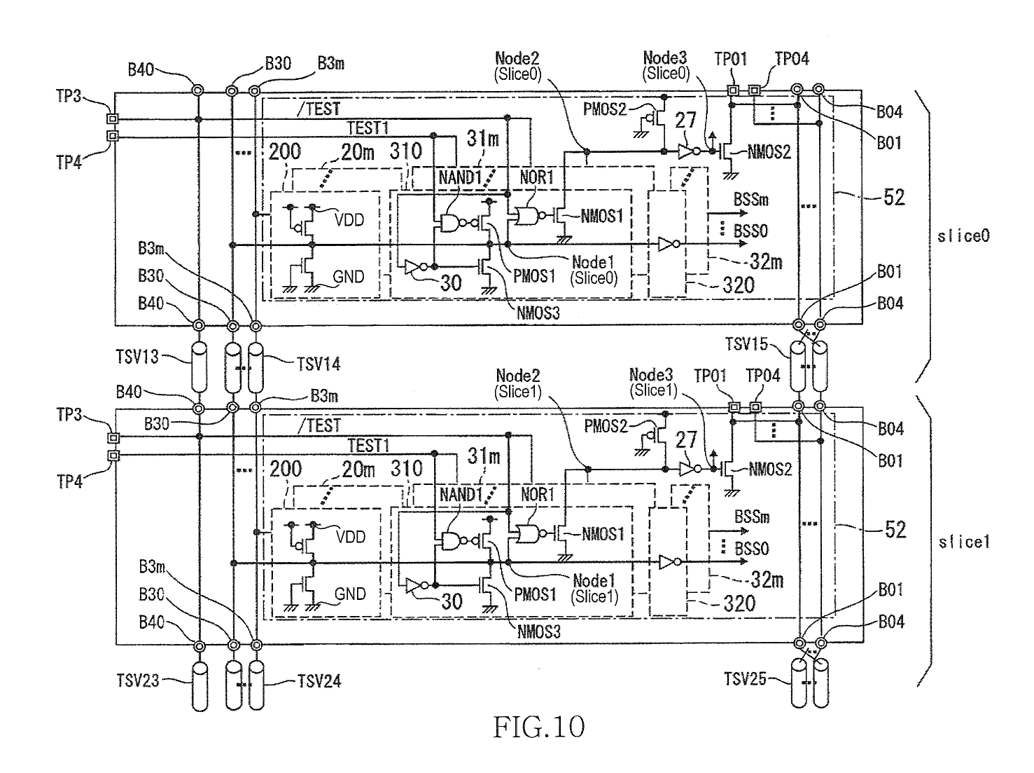

A circuit configuration of the test circuit unit 52 is explained in detail with reference to FIG. 10. The test circuit unit 52 is used to perform the other of the operation tests described with reference to FIG. 5.

The test circuit unit 52 buffers boundary scan signals BSS0 to BSSm supplied from bump electrodes B30 to B3m, and outputs the boundary scan signals BSS0 to BSSm to the BS control unit 50. The BS control unit 50 transmits and receives the signals during a test operation that includes boundary scan. A test operation using the test signal /TEST and a test signal TEST1 will be described later in conjunction with the configuration of the test circuit unit 52.

According to the boundary scan signals BSS0 to BSSm supplied from the test circuit unit 52, the BS control unit 50 transmits and receives a plurality of boundary scan signals BSSa to/from the BS circuit unit 53a of the channel a. The boundary scan signals BSSa include a scan data input signal SDI, a scan data output signal SDO, and a plurality of boundary scan control signals BSCS. The plurality of boundary scan control signals BSCS include a scan clock SCK, a parallel out enable signal POE, a serial/parallel input selection signal SSH, a parallel output data selection signal PDS, and a serial output enable signal SOE.

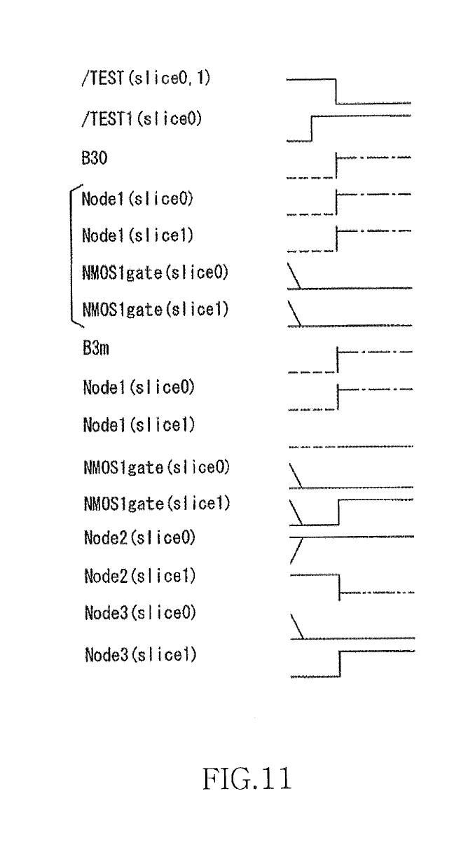

With respect to the test circuit unit 52, the test signal to be supplied to the node Node1 is not supplied from the test pads but is generated inside the test circuit unit 52. The other configurations of the test circuit unit 52 are basically the same as that of the test circuit unit 51 shown in FIG. 8. The operation of the test circuit unit 52 is shown in FIG. 11.

The test pads and bump electrodes shown in FIG. 10 are designated by the same reference symbols as those of the test pads and bump electrodes shown in FIG. 5.

A plurality of penetration electrodes TSV14 and a plurality of penetration electrodes TSV15 are formed in the same chip C1 as Slice0, for example. A plurality of penetration electrodes TSV24 and a plurality of penetration electrodes TSV25 are formed in the same chip C2 as Slice1, for example.

The penetration electrodes TSV14 and TSV24 are formed as penetration electrodes TSV1 shown in FIG. 4A. The bump electrodes B30 to B3m of the chips C1 to C4 are connected to the respective corresponding penetration electrodes TSV14, TSV24, etc. The bump electrodes B30 to B3m of the respective chips are connected in common via the penetration electrodes. Signals appearing on the nodes Node1 (Slice0) of the chip C1 are input to the respective bump electrodes in common.

The penetration electrodes TSV15, TSV25, and the like are formed as penetration electrodes TSV3 shown in FIG. 4C. Each chip includes four penetration electrodes (referred to as penetration electrodes TSV3Sa, TSV3Sb, TSV3Sc, and TSV3Sd as described above).

For example, the test pad TP01 of the chip C1 is connected to the bump electrode B01 of the chip C1. The bump electrode B01 of the chip C1 is connected to the bump electrode B02 of the chip C2 via the penetration electrode TSV3Sa (a penetration electrode TSV15 shown in FIG. 10). The bump electrode B02 of the chip C2 is connected to the bump electrode B03 of the chip C3 via the penetration electrode TSV3Sb (a penetration electrode TSV25 shown in FIG. 10). The bump electrode B03 of the chip C3 is connected to the bump electrode B04 of the chip C4 via a penetration electrode TSV3Sc (not shown in FIG. 10).

Consequently, when a signal is supplied to the test pad TP01 of the chip C1, the signal can be supplied to the bump electrode B01 and the test pad TP01 of the chip C1 alone without being supplied to the bump electrodes B01 and the test pads TP01 of the chips C2 to C4.

Similarly, when a signal is supplied to the test pad TP02 of the chip C1, the signal can be supplied to the bump electrode B01 and the test pad TP01 of the chip C4 alone without being supplied to the bump electrodes B01 and the test pads TP01 of the chips C1 to C3.

Similarly, when a signal is supplied to the test pad TP03 of the chip C1, the signal can be supplied to the bump electrode B01 and the test pad TP01 of the chip C3 alone without being supplied to the bump electrodes B01 and the test pads TP01 of the chips C1, C2, and C4.

Similarly, when a signal is supplied to the test pad TP04 of the chip C1, the signal can be supplied to the bump electrode B01 and the test pad TP01 of the chip C2 alone without being supplied to the bump electrodes B01 and the test pads TP01 of the chips C1, C3, and C4.

As seen above, when signals are supplied to the test pads TP01 to TP04 of the chip C1 (Slice0) and the gate potentials of the NMOS transistors NMOS2 are changed, a potential change occurs on the potentials of the bump electrodes B01 and the test pads TP01 of the chips C1 (Slice0) to C4 (Slice3). This makes it possible to obtain the test result (whether a current flows through the third paths including the penetration electrodes TSV15) on each chip (slice).

Differences of the connections of the internal circuits of the test circuit unit 52 in the chip C1 from those of the test circuit unit 51 will be described. Note that the chips C1 to C4 have the same circuit configuration.

The bump electrode B30 is connected to an electrostatic breakdown protection element 200, a test circuit 310, and an input buffer 320.

The test circuit 310 includes a NAND circuit NAND1, a PMOS transistor PMOS1, an NMOS transistor NMOS3, and an inverter circuit 30 in addition to the NOR circuit NOR1 and NMOS transistor NMOS1 of the test circuit 210.

Either one of two input nodes of the NAND circuit NAND1 is connected to the test pad TP4. The other of the two input nodes is connected to the output node of the inverter circuit 30. The output node of the NAND circuit NAND1 is connected to the gate electrode of the PMOS transistor PMOS1.

The source of the PMOS transistor PMOS1 is connected to the power supply VDD. The gate electrode thereof is connected to the output node of the NAND circuit NAND1. The drain is connected to the node Node1 (Slice0).

The input node of the inverter circuit 30 is connected to the test pad TP3 like the input node of the NOR circuit NOR1. The output node of the inverter circuit 30 is connected to the gate electrode of the NMOS transistor NMOS3.

The drain of the NMOS transistor NMOS3 is connected to the node Node1 (Slice0). The gate electrode thereof is connected to the output node of the inverter circuit 30. The source is grounded.

The circuit constants of the PMOS transistor PMOS1 and the NMOS transistor NMOS3 are set so that the node Node1 becomes such an “H” level that the NOR circuits NOR1 of the chips C1 to C4 output an “L” level to turn off the NMOS transistors NMOS1 even when the PMOS transistor PMOS1 of the chip C1 and the NMOS transistors NMOS3 of the chips C1 to C4 are turned on. For example, if the NOR circuit NOR1 has a logic threshold ½ the power supply voltage, the circuit constants (channel lengths L and channel widths W) are set so that the PMOS transistor PMOS1 has an ON current four times as high as or higher than the ON current of the NMOS transistor NMOS3.

The input node of the input buffer 320 is connected to the node Node1 (first layer). The output node of the input buffer 320 is connected to the BS control unit 50 shown in FIG. 5. The input buffer 320 buffers the boundary scan signal BSS0 supplied to the bump electrode B30, and outputs the boundary scan signal BSS0 to the BS control unit 50.

Like the bump electrode B30, the bump electrodes B31 to B3m are connected to the respective same circuits as the electrostatic breakdown protection element 200, test circuit 310, and input buffer 320.

Hereinafter, an electrostatic breakdown protection element, a test circuit, and an input buffer connected to a bump electrode B3i (i=0 to m) will be referred to as an electrostatic breakdown protection element 20i, a test circuit 31i, and an input buffer 321, respectively. The input buffers 32i buffer the boundary scan signals BSSi supplied to the bump electrodes B3i, and output the buffered boundary scan signals BSSi to the BS control unit 50.

In each test circuit 31i (i=0 to m), one of the two input nodes of the NAND circuit NAND1 is connected to the test pad TP4.

The node Node2 (first layer) is connected to the input node of the inverter circuit 27. The output node of the inverter circuit 27 is the node Node3 (Slice0). The gate electrode of the NMOS transistor NMOS2 is connected to the node Node3 (first layer). The drain is connected to the test pad TP01 and the bump electrode B01. The source is grounded.

The node Node2 (first layer) is also connected to the PMOS transistor PMOS2. The source of the PMOS transistor PMOS2 is connected to the power supply VDD. The gate electrode thereof is grounded. The drain of the PMOS transistor PMOS2 is connected to the connection node Node2 (Slice0). In each chip, the circuit constants of the PMOS transistor PMOS2 and the NMOS transistor NMOS2 are set so that the node Node2 becomes such an “L” level that the inverter circuit 27 outputs an “H” level to turn on the NMOS transistor NMOS2 even when at least one of the (m+1) NMOS transistors NMOS1 is turned on. For example, if the inverter circuit 27 has a logic threshold ½ the power supply voltage VDD, the circuit constants (channel lengths L and channel widths W) are set so that a single NMOS transistor NMOS1 has an ON current higher than the ON current of the PMOS transistor PMOS2.

Next, an operation for detecting a defective connection of the input terminals of the chips C1 to C4, i.e., terminals that are not capable of direct contact from outside nor subjected to the boundary scan test method by using the foregoing configuration will be described.

The following description is given on the assumption that the connection between the bump electrode B3m formed on the chip C1 (Slice0) and the bump electrode B3m formed on the chip C2 (Slice1) via a penetration electrode TSV14 is open.

FIG. 11 is a chart showing the operation waveforms of the test circuit unit 52 shown in FIG. 10.

In the following description, the bump electrodes B30 to B3m are typified by the bump electrode B30 except the bump electrode B3m.

In the chip C1 (Slice0), the test signal /TEST of an “H” level is input to the test pad TP3. The test signal TEST1 of an “L” level” is input to the test pad TP4.

The node Node1 (Slice0) of the chip C1 and the node Node1 (Slice1) of the chip C2 have a potential of a floating “L” level since there is no connection from outside.

The node Node2 (Slice0) of the chip C1 and the node Node2 (Slice1) of the chip C2 have a potential of an “H” level because the respective PMOS transistors PMOS2 are on. The node Node3 (Slice0) of the chip C1 and the node Node3 (Slice1) of the chip C2 therefore have a potential of an “L” level, and the NMOS transistors NMOS2 in both the chips are off.

Next, in the chip C1 (Slice0), the test signal TEST1 supplied to the test pad TP4 is changed from the “L” level to an “H” level.

In the chip C1 (Slice0), the test signal /TEST supplied to the test pad TP3 is changed from the “H” level to an “L” level.

In the test circuit 310 of the chip C1, the PMOS transistor PMOS1 and the NMOS transistor NMOS3 turn on. In the test circuit 310 of the chip C2, the NMOS transistor NMOS3 turns on. Since the circuit constants of the PMOS transistor PMOS1 and the NMOS transistor NMOS3 in each chip are set as described above, the potential of the node Node1 (Slice0) connected to the bump electrode B30 of the chip C1 becomes an “H” level such that the NOR circuit NOR1 will not output an “H” level.

Since the penetration electrode TSV14 between the bump electrode B30 of the chip C1 and the bump electrode B30 of the chip C2 properly connects the chips C1 and C2, the node Node1 (Slice1) connected to the bump electrode B30 becomes an “H” level equivalent to that of the node Node1 (Slice0) connected to the bump electrode B30 of the chip C1.

In the test circuit 31m of the chip C1, the PMOS transistor PMOS1 and the NMOS transistor NMOS3 turn on. The node Node1 (Slice0) connected to the bump electrode B3m of the chip C1 becomes an “H” level.

The penetration electrode TSV14 between the bump electrode B3m of the chip C1 and the bump electrode B3m of the chip C2 is open and does not connect the chips C1 and C2. When the NMOS transistor NMOS3 turns on, the node Node1 (Slice1) connected to the bump electrode B3m of the chip C2 is grounded to change from an floating “L” level to an “L” level.

The NOR circuit NOR1 connected to the bump electrode B30 of the chip C1 maintains the output of the L″ level since the other input (node Node1 (Slice0)) is at an “H” level. This prevents the NMOS transistor NMOS1 from turning on.

The NOR circuit NOR1 connected to the bump electrode B3m of the chip C1 maintains the output of the “L” level since the other input (node Node1 (Slice0)) is at an “H” level. This prevents the NMOS transistor NMOS1 from turning on.

As a result, the potential of the node Node2 (Slice0) of the chip C1 is maintained at an “H” level, and the potential of the node Node3 (Slice0) of the chip C1 is maintained at an “L” level. The NMOS transistor NMOS2 remains off.

Consequently, when a signal of an “H” level is supplied to the test pad TP01 of the chip C1, no potential change occurs on the signal. It should be appreciated that the test pads TP01 of the chips C2 to C4 are not connected to the test pad TP01 of the chip C1 since the penetration electrodes TSV15 and the like including the bump electrodes connected to the test pads are spirally connected as described above. The test pads TP01 of the chips C2 to C4 therefore have no effect on the potential change of the signal of the “H” level applied to the test pad TP01 of the chip C1.

The NOR circuit NOR1 connected to the bump electrode B30 of the chip C2 maintains the output of the “L” level since the other input (node Node1 (Slice1)) is at an “H” level. This prevents the NMOS transistor NMOS1 from turning on.

Now, the NOR circuit NOR1 connected to the bump electrode B3m of the chip C2 outputs a signal of an “H” level since the other input (node Node1 (Slice1)) is at an “L” level. This turns the NMOS transistor NMOS1 on.

As a result, the potential of the node Node2 (Slice1) of the chip C2 changes from an “H” level to an “L” level, and the potential of the node Node3 (Slice1) of the chip C2 changes from an “L” level to an “H” level. The NMOS transistor NMOS2 therefore turns on.

Consequently, when a signal of an “H” level is supplied to the test pad TP04 of the chip C1, the signal undergoes a potential change, from which it can be detected that the chips C1 and C2 are not connected to each other, i.e., that the input terminal of the chip C2 is not electrically connected to outside.

It should be appreciated that the test pads TP01 of the chips C1, C3, and C4 are not connected to the test pad TP01 of the chip C2 since the penetration electrodes TSV15 and the like including the bump electrodes connected to the test pads are spirally connected as described above. The test pads TP01 of the chips C1, C3, and C4 therefore have no effect on the potential change of the signal of the “H” level applied to the test pad TP04 of the chip C1.

As has been described above, the stacked semiconductor device 20 includes s first semiconductor chip (chip C2) and a second semiconductor chip (chip C2).

The chip C2 (second semiconductor chip) includes a test circuit arranged between its own terminals (bump electrodes B30 to B3m) and input buffers (input buffers 320 to 32m). The test circuit includes a node (node Node1 (Slice1) of the chip C2) that is charged according to first signals (signals that are generated on the nodes Node1 connected to the bump electrodes B30 to B3m of the first chip C1, respectively, and input to the second chip C2 through the bump electrodes B30 to B3m, respectively) supplied from the chip C1 (first semiconductor chip) and is discharged according to a second signal (test signal /TEST) supplied from the chip C1 (first semiconductor chip)).

The stacked semiconductor device 20 further includes first paths that transfer the first signals (signals that are generated on the nodes Node1 connected to the bump electrodes B30 to B3m of the first chip C1, respectively, and input to the second chip C2 through the bump electrodes B30 to B3m, respectively) from the first semiconductor chip (chip C1) to the second semiconductor chip (chip C2). The first paths include penetration electrodes (penetration electros TSV14 connecting the bump electrodes B30 to B3m of the chip C1 to the bump electrodes B30 to B3m of the chip C2, respectively). The stacked semiconductor device 20 further includes a second path that transfers the second signal (test signal /TEST) from the chip C1 (first semiconductor chip) to the second chip (chip C2). The second path includes a penetration electrode (penetration electrode TSV13 which connects the bump electrode B40 of the chip C1 to the bump electrode B40 of the chip C2).

The first signals are supplied to the input buffers (input buffers 320 to 32m) of the second semiconductor chip. If the first paths include any defect such as an open penetration electrode, the corresponding node (node Node1 (Slice1)) fails to be provided with a first signal. The node is thus not precharged and maintains a discharged state. In response to such a state, the node Node2 is discharged.

To detect the potential change on the node, the chip C1 (first chip) and the chip C2 (second chip) include third paths including penetration electrodes (paths including the penetration electrodes TSV15). The third paths are capable of independently inputting signals from outside the semiconductor device to the respective chips and pass a current according to the potential of the node (node Node2 (Slice1)).

Consequently, if any one of the penetration electrodes TSV14 and the like connecting the chips (slices) has a defective connection, a current flows through the path (third path) that includes the penetration electrode connected to the one of the test pads TP01 to TP04 of the chip C1 corresponding to that slice. This makes it possible to determine the slice where the first paths including the penetration electrodes TSV14 and the like have the defective connection.

As described above, according to the present embodiment, the input terminals of the first semiconductor chip (the bump electrodes B20 to B2n of the test circuit unit 51 and the bump electrodes B30 to B3m of the test circuit unit 52) are connected to the input terminals (bump electrodes B20 to B2n and B30 to B3m) of the second semiconductor chip.

A first signal (test signal /TEST of the test circuit unit 51) or a second signal (test signal /TEST of the test circuit unit 52) from the first semiconductor chip is then transferred to the second semiconductor chip.

This can produce a potential change on nodes of the test circuits of the second semiconductor chip (the node Node2 of the test circuit unit 51 and the node Node1 of the test circuit unit 52). For example, a current can be passed through the second semiconductor chip from the terminals capable of direct contact (the test pads TP11 to TP14 of the test circuit unit 51 and the test pads TP01 to TP04 of the test circuit unit 52) according to the voltages of the nodes of the test circuits in the second semiconductor chip. With such a configuration, it is possible to test whether the terminals of the second semiconductor chip (the bump electrodes B20 to B2n of the test circuit unit 51 and the bump electrodes B30 to B3m of the test circuit unit 52) and the input terminals of the second semiconductor chip (the bump electrodes B20 to B2n and B30 to B3m) are electrically connected to outside. This makes it possible in the stacked semiconductor device 20 to detect a defective connection of the terminals that are not capable of direct contact from outside nor subjected to the boundary scan test method (the bump electrodes B20 to B2n and B30 to B3m).

The technical concept of the present application is applicable to a semiconductor device having a boundary scan function. The forms of the circuits in the circuit blocks disclosed in the drawings or circuits generating other control signals are not limited to the circuit forms disclosed in the embodiment.

Various disclosed elements may be combined or selected in a variety of ways within the scope of the claims of the present invention. It will be understood by those skilled in the art that various changes and modifications may be made to the present invention according to the entire disclosure and technical concept including the claims.

For example, the configuration of the test circuit unit 51 may be applied to the test circuit unit 52, and the configuration of the test circuit unit 52 may be applied to the test circuit unit 51. In other words, the configurations of the test circuit units 51 and 52 may be replaced with each other. The configuration of either one of the test circuit units 51 and 52 may be used for both the test circuit units 51 and 52.

What is claimed is:

1. A semiconductor device comprising:
a first chip including first and second surfaces opposed to each other, first, second and third terminals on the first surface, and a fourth terminal on the second surface, the first and fourth terminals being electrically coupled to each other through a penetration electrode penetrating a semiconductor substrate of the first chip, and a first internal node of which an electrical potential being changed in response to an electrical potential of the first terminal; and
a second chip stacked with the first chip, the second chip including a third surface facing to the second surface of the first chip, a fourth surface opposed to the third surface, a fifth terminal on the third surface electrically coupled to the fourth terminal of the first chip, sixth and seventh terminals on the third surface, and a second internal node of which an electrical potential being changed in response to an electrical potential of the fifth terminal;
the first internal node of the first chip being electrically coupled to both the second terminal of the first chip and the sixth terminal of the second chip, the second internal node of the second chip being electrically coupled to both the third terminal of the first chip and the seventh terminal of the second chip.

2. The semiconductor device as claimed in claim 1, wherein the first, fourth and fifth terminals are arranged in line in a first direction perpendicular in common to the first, second, third and fourth surfaces, the second and seventh terminals being arranged in line in the first direction, and the third and sixth terminals being arranged in line in the first direction.

3. The semiconductor device as claimed in claim 1, wherein the second chip further includes a memory circuit and a test circuit electrically coupled to the fifth terminal, the test circuit performing a test operation on the memory circuit in response to a test signal supplied from the fifth terminal.

4. The semiconductor device as claimed in claim 1, further comprising a controller chip on which the first and second chips are mounted, wherein each of the first and second chips includes a memory circuit and the controller chip is configured to perform a read/write operation on the memory circuit of each of the first and second chips.

5. The semiconductor device as claimed in claim 4, further comprising a package board including a fifth surface on which the controller chips and the first and second chips are mounted, a sixth surface opposed to the fifth surface, and a plurality of solder balls on the sixth surface, the solder balls being electrically coupled to the controller chip, the controller chip being configured to perform the read/write operation on the memory circuit of each of the first and second chips in response to control signals supplied with the solder balls.

6. The semiconductor device as claimed in claim 5, wherein the first, second, third and fourth terminals of the first chip are electrically independent of each of the solder balls.

7. The semiconductor device as claimed in claim 6, wherein the fifth, sixth and seventh terminals of the second chip are electrically independent of each of the solder balls.
